(19) United States
(12) Patent Application Publication
(10) Pub. No.: US 2013/0047916 A1
(43) Pub. Date: Feb. 28, 2013

(54) VAPOR GROWTH APPARATUS AND VAPOR GROWTH METHOD

(71) Applicants: Michio NISHIBAYASHI, Shizuoka-ken (JP); Takumi YAMADA, Shizuoka-ken (JP); Yuusuke SATO, Tokyo (JP)

(72) Inventors: Michio NISHIBAYASHI, Shizuoka-ken (JP); Takumi YAMADA, Shizuoka-ken (JP); Yuusuke SATO, Tokyo (JP)

(21) Appl. No.: 13/598,792

(22) Filed: Aug. 30, 2012

(30) Foreign Application Priority Data
Aug. 31, 2011 (JP) 2011-189354

(51) Int. Cl. C30B 25/10; C30B 25/16; C30B 25/12

(52) U.S. Cl. 117/86; 118/725; 118/712; 117/98

(57) ABSTRACT

A vapor growth apparatus including: a reaction chamber configured to lod a wafer; a gas supply mechanism which supplies process gas into the reaction chamber; a support unit for placing the wafer; a heater for heating the wafer from below; a rotation control unit for rotating the wafer; a gas exhaust mechanism including an exhaust port which exhausts gas from the reaction chamber; a reflector provided below the heater for reflecting heat from the heater onto a rear face of the wafer; and a vertical drive unit for vertically moving the reflector.

### CROSS REFERENCE TO RELATED APPLICATION

This application is based upon and claims the benefit of priority from the prior Japanese Patent Application No. 2011-189354 filed in Japan on Aug. 31, 2011; the entire contents of which are incorporated herein by reference.

### FIELD

The present invention relates to a vapor growth apparatus and a vapor growth method.

### BACKGROUND

The present invention relates to a vapor growth apparatus and a vapor growth method used for forming a film by, for example, supplying process gas onto a semiconductor wafer.

In recent years, due to requirements for further price reduction and higher performance of semiconductor devices, there has been required higher quality, such as improvement in film thickness uniformity, as well as high productivity in a film formation process.

A single-wafer-processing type vapor growth apparatus has been used to satisfy such requirements. In a single-wafer-processing type phase growth apparatus, a film is formed on a wafer in a reaction chamber by, for example, a rear face heating method for supplying process gas while rapidly rotating the wafer at equal to or higher than 900 rpm, and heating the wafer from the rear face thereof by using a heater (Refer to Japanese patent application laid-open No. 11-67675, for example).

In such a vapor growth apparatus, film thickness distribution of a film which is formed on a wafer depends on temperature distribution. An accurate control of the temperature distribution is therefore required.

Normally, the temperature distribution can be controlled to some degree by optimization of heater patterns as well as by detecting temperatures of a central portion and a peripheral portion of a wafer and controlling outputs of heaters heating the central portion and the peripheral portion of the wafer, respectively, so as to maintain a constant temperature difference.

On the other hand, repeated film formation causes deterioration of the heaters. The temperature distribution has a tendency to vary widely due to the deterioration. It is therefore required to increase the frequency of replacement of heaters in order to maintain the film thickness uniformity.

There have been higher requirements for improvement in the film thickness uniformity in order to improve element characteristics, such as pressure resistance of semiconductor elements, as well as yield and reliability. Hence, optimization of the heater patterns has been considered in various manners in order to minimize the variation in temperatures in the surface of a wafer. However, even by optimization of heater patterns and an appropriate control of heater outputs, it is difficult to minimize an increasing variation in temperatures in the surface of the wafer which is associated with deterioration of the heaters.

Hence, it is required to provide a vapor growth apparatus and a vapor growth method capable of controlling temperature distribution of a wafer and further improving the film thickness uniformity.

### SUMMARY

A vapor growth apparatus according to an aspect of the present invention includes: a reaction chamber configured to load a wafer; a gas supply mechanism configured to supply process gas into the reaction chamber; a support unit configured to place the wafer; a heater configured to heat the wafer from below;

a rotation control unit configured to rotate the wafer;

a gas exhaust mechanism including an exhaust port exhausting gas from the reaction chamber; a reflector provided below the heater configured to reflect heat from the heater onto a rear face of the wafer; and a vertical drive unit configured to vertically moving the reflector.

A vapor growth method according to an aspect of the present invention includes: holding a wafer at a predetermined position inside a reaction chamber; heating a rear face of the wafer with a heater while vertically moving a reflector that is provided below the heater, thereby heating the wafer at a predetermined temperature while controlling temperature distribution of the wafer; and supplying process gas onto the wafer while rotating the wafer, thereby forming a film on the wafer.

### BRIEF DESCRIPTION OF THE DRAWINGS

FIG. 1 is a cross-sectional view showing a structure of an epitaxial film formation apparatus according to an aspect of the present invention.

FIG. 2 is a block diagram explaining a structure of a temperature control system taken out of FIG. 1.

FIG. 3 is a flowchart for explaining a temperature control operation according to the temperature control system shown in FIG. 2.

FIG. 4 is a diagram showing an example of temperature distribution in a surface of a wafer according to an aspect of the present invention.

FIG. 5 is a cross-sectional view showing a structure of an epitaxial film formation apparatus according to an aspect of the present invention.

FIG. 6 is a partly cross-sectional view showing a structure of an epitaxial film formation apparatus according to an aspect of the present invention.

FIG. 7 is a partly enlarged view of an epitaxial film formation apparatus according to an aspect of the present invention.

FIG. 8 is a diagram showing a reflector of an epitaxial film formation apparatus according to an aspect of the present invention.

### DETAILED DESCRIPTION

Referring to the accompanying drawings, embodiments of the present invention will be described below.

### First Embodiment

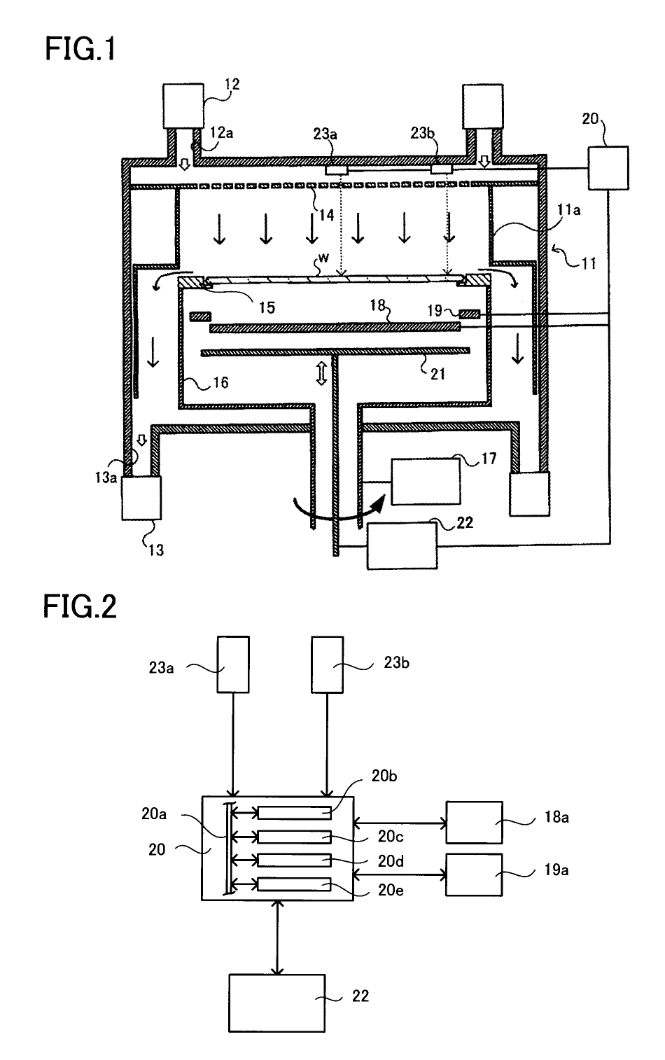

FIG. 1 shows a cross-sectional view of a vapor growth apparatus according to the present embodiment. As illustrated in FIG. 1, in a reaction chamber 11 in which a wafer w is subjected to film formation, there is provided a quartz cover 11a so as to cover an inner wall thereof as necessary.

At an upper portion of the reaction chamber 11, there is provided a gas supply port 12a connected to a gas supply unit 12 for supplying process gas including source gas and carrier gas. At a lower portion of the reaction chamber 11, there is disposed a gas exhaust port 13a connected to a gas exhaust unit for exhausting gas to two places, for example, thereby controlling a pressure inside the reaction chamber to be constant (e.g. normal pressure).

Below the gas supply port 12a, there is provided a rectifying plate 14 having fine through holes for rectifying the process gas supplied and supplying the rectified gas.

Below the rectifying plate 14, there is provided an annular holder 15, which is a support unit for placing the wafer w and is made of SiC, for example. Note that the support unit may be a disc-shaped susceptor. The holder 15 is disposed on a ring 16, which is a rotation member. The ring 16 is connected, via a rotation shaft that rotates the wafer w at a predetermined rotation speed, to a rotation control unit 17, which is constituted by a motor or the like.

Inside the ring 16, there is disposed a heater for heating the wafer w, which is constituted by an in-heater 18 and an out-heater 19, which are made of SiC, for example. The in-heater 18 and the out-heater 19 are connected to a temperature control unit 20, which controls the in-heater 18 and the out-heater 19 so that they respectively reach a predetermined temperature at a predetermined speed of increase/decrease in temperature, or controls a temperature difference between the central portion and the peripheral edge portion of the wafer w to be a predetermined temperature.

There is also provided, below the in-heater 18 and the out-heater 19, a disc-shaped reflector 21 for reflecting the heat coming downwardly from them to effectively heat the wafer w. The reflector 21 is connected to a vertical drive unit 22, therefore it can vertically move within a predetermined stroke. The vertical drive unit 22 has a position detecting function, allowing the reflector 21 to move to a predetermined position within the stroke.

The vertical drive unit 22 is connected to a temperature control unit 20, therefore it can control a position of the reflector 21 so that the temperature distribution in a surface of the wafer w to be in a predetermined range.

At an upper portion of the reaction chamber 11, there are disposed radiation thermometers 23a and 23b, which are temperature detection units for detecting temperature distributions of a central portion and a peripheral edge portion of the wafer w. The radiation thermometers 23a and 23b are connected to the temperature control unit 20.

FIG. 2 is a block diagram explaining a structure of a temperature control system taken out of FIG. 1. In the drawing, the same or corresponding reference numerals are used to designate constituent elements which are the same as or corresponding to those illustrated in FIG. 1. The temperature control unit 20 is constituted by, for example, a micro computer including an interface unit 20b, an operation unit 20c, a data storage unit 20d and a program storage unit 20e, which are connected to a common bus 20a. Temperatures measured by the radiation thermometers 23a and 23b are supplied to the temperature control unit 20 as input signals, in which a temperature detection unit includes the radiation thermometers 23a and 23b are for detecting the above-described temperature distributions of the central portion and the peripheral edge portion of the wafer w. The temperature control unit 20 is connected to an in-heater drive unit 18a and an out-heater drive unit 19a for supplying electric power to the in-heater 18 and the out-heater 19, thereby heating them, enabling information exchanges between the temperature control unit 20 and each of the in-heater drive unit 18a and the out-heater drive unit 19a. The temperature control unit 20 is also connected to the vertical drive unit 22 which vertically drives the reflector 21, enabling information exchanges between each other.

Using such a semiconductor manufacturing device, a Si epitaxial film is formed on a φ200 mm wafer w, for example.

Firstly, with a robot hand (not shown) or the like, the wafer w is loaded into the reaction chamber 11 and placed on a lift pin (now shown). And then the lift pin is lowered, thereby placing the wafer w on the holder 15.

Then, the temperature control unit 20 controls respective temperatures.

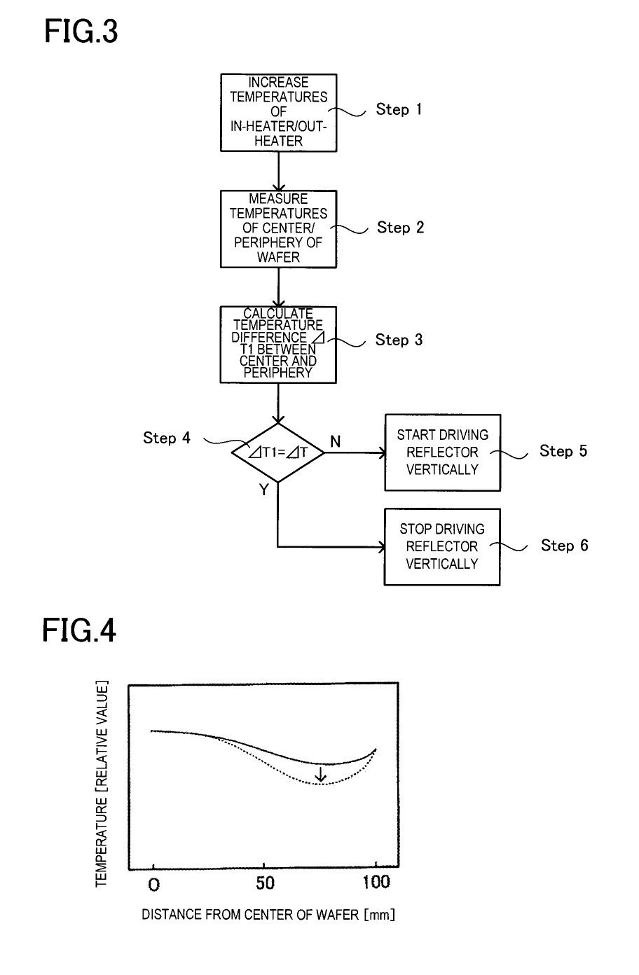

FIG. 3 is a flowchart for explaining a temperature control operation.

Firstly, the temperature control unit 20 controls the in-heater drive unit 18a and the out-heater drive unit 19a, thereby increasing heater outputs so that the in-heater 18 and the out-heater 19 reach 1500-1600° C., for example (Step 1). At the same time, the temperature control unit 20 measures the temperatures of the central portion and the peripheral portion of the wafer w, which have been heated in the above-described manner, by the radiation thermometers 23a and 23b (Step 2), and increases the heater outputs until the temperatures reading on the thermometers reach 1100° C., for example. Secondly, the temperature control unit 20 calculates a difference value [symbol] T1 between the temperatures measured by the radiation thermometers 23a and 23b (Step 3), and compares the difference value [symbol] T1 with a preset optimum difference value [symbol] T (Step 4). As a result of the comparison, if both difference values are inconsistent with each other, the temperature control unit 20 sends an order signal to the vertical drive unit 22 to vertically drive the reflector 21 (Step 5).

Downward movement of the reflector 21 herein causes heat to radiate from the in-heater 18 and the out-heater 19 toward the outer circumferences, thereby reducing the amount of heat that the central portion of the wafer w receives from the reflector. On the other hand, upward movement of the reflector 21 reduces losses caused by the radiation from the in-heater 18 and the out-heater 19 toward the outer circumferences, thereby increasing the amount of heat that the central portion of the wafer w receives from the reflector.

The temperature control unit 20 stops the vertical drive unit 22 from vertically driving the reflector 21 at the time when the temperature difference [symbol] T1 becomes the optimum difference value [symbol] T by the adjustment of a distance between the reflector 21 and each of the in-heater 18 and the out-heater 19 by the vertical drive unit 22.

At the same time, the rotation control unit 17 rotates the wafer w at 900 rpm, for example.

The process gas, which has the flow volume controlled by the gas supply control unit 12 and is mixed, is supplied in a rectified state, via the rectifying plate 14, onto the wafer w which has reached a predetermined temperature and has been rotated as described above. The process gas is supplied at 50SLM, for example, having Dichlorosilane (SiH2Cl2) as source gas, for example, diluted by diluent gas such as H₂ gas to have a predetermined concentration (e.g. 2.5%).

On the other hand, exhaust gas including surplus process gas and reaction by-product is exhausted from the gas exhaust port 13a via the gas exhaust unit 13, thereby controlling a pressure inside the reaction chamber 11 to be constant (e.g. normal pressure).

Thus, a Si epitaxial film having a predetermined film thickness is formed on the wafer w.

FIG. 4 herein shows an example of temperature distribution in the surface of the wafer w. As illustrated with a solid line in FIG. 4, the temperature decreases from the center toward the outer circumferences and increases at the peripheral edge portion. The deterioration of heaters, for example, decreases the temperature at the intermediate portion and, as a consequence, temperatures vary widely as illustrated with a dashed line.

Normally, the outputs of the in-heater 18 and the out-heater 19 control the temperature distribution in the surface of the wafer w. In addition, the vertical movement of the reflector 21 controls reflection of radiation heat from the in-heater 18 and the out-heater 19, thereby enabling a control with a higher degree of accuracy.

According to the present embodiment, the control of the temperature at the central portion of the wafer was described above enables the minimization of variation in temperatures in the surface of the wafer w. It is also possible to minimize variation in temperatures in the surface of the wafer w which is associated with deterioration of heaters. Accordingly, the frequency of replacement of heaters can be reduced and the productivity can be improved.

### Second Embodiment

A configuration of an epitaxial film formation apparatus according to the present embodiment is equal to that according to the first embodiment. However, a lifting unit for loading/unloading a wafer and a vertical drive unit of a reflector are formed integrally.

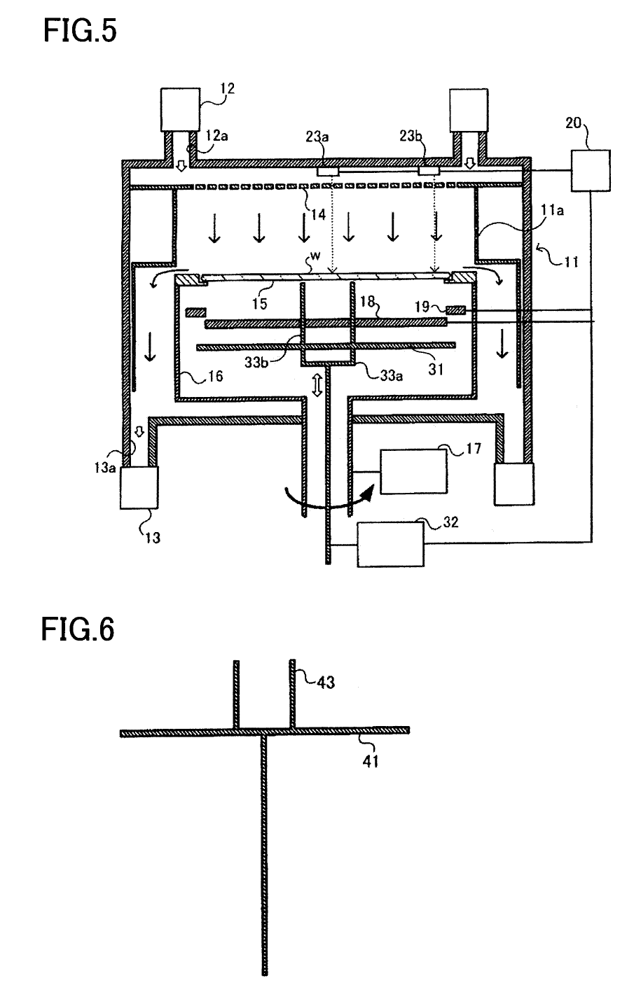

FIG. 5 shows an epitaxial film formation apparatus, which is a semiconductor manufacturing device according to the present embodiment. Note that, in FIG. 5, the same reference numerals are used to designate constituent elements which are the same as those illustrated in FIG. 1, and the explanation is omitted.

As illustrated in FIG. 5, there is provided, below the in-heater 18 and the out-heater 19, a disc-shaped reflector 31 for reflecting the heat coming downwardly from them to effectively heat the wafer w. The reflector 31 is connected to a vertical drive unit 32, therefore it can vertically move within a predetermined stroke.

The vertical drive unit 32 is further connected, via a lift pin base 33a, to a plurality of lift pins 33b for supporting the wafer when the wafer w is loaded into the reaction chamber or unloaded from the reaction chamber and lifting the wafer w respect to a wafer placing support unit. That is to say, the lift pins 33b are provided on the lift pin base 33a in a standing manner so as to extend upwardly penetrating through the in-heater 18 and the reflector 20. The lift pins 33b supports a lower face of the wafer w with respective tips thereof, thereby vertically moving the wafer w. The vertical drive unit 32 has a position detecting function, as in the first embodiment, and is connected to the temperature control unit 20. Therefore, as in the first embodiment, it enables the reflector 31 to move to a predetermined position within a stroke corresponding to the temperature distribution in the surface of the wafer w.

According to the present embodiment, a range of movement of a reflector is within a range where lift pins do not move a wafer upwardly. However, by allowing an existing wafer lifting unit to have a vertical driving function of the reflector, it is realized without providing a new space due to complicated configurations inside a reaction chamber. Accordingly, as in the first embodiment, the control of the temperature at the central portion of the wafer w enables the minimization of variation in temperatures in the surface of the wafer w. It is also possible to minimize variation in temperatures in the surface of the wafer w which is associated with deterioration of heaters. Accordingly, the frequency of replacement of heaters can be reduced and the productivity can be improved.

Note that, as illustrated in FIG. 6, using the reflector 41 as a lift pin base, lift pins 43 may be herein disposed on the reflector. Such a configuration enables the enhancement of further space-saving.

### Third Embodiment

A configuration of an epitaxial film formation apparatus according to the present embodiment is equal to that according to the first embodiment. However, a reflector is divided into a central portion and a peripheral edge portion.

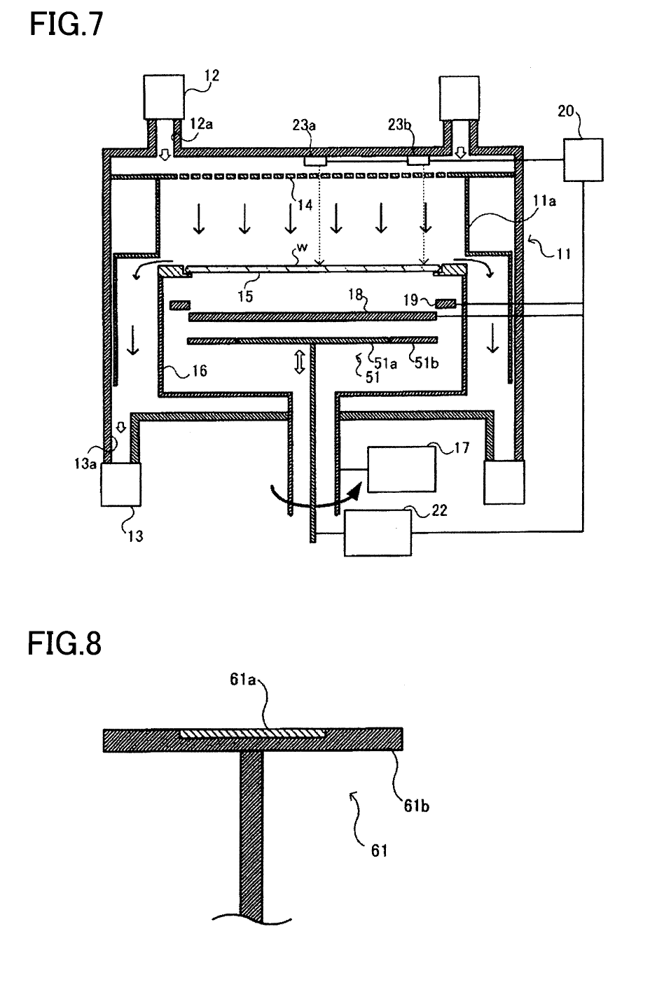

FIG. 7 shows an epitaxial film formation apparatus, which is a semiconductor manufacturing device according to the present embodiment. Note that, in FIG. 7, the same reference numerals are used to designate constituent elements which are the same as those illustrated in FIG. 1, and the explanation is omitted.

As illustrated in FIG. 7, a disc-shaped reflector 51 is divided into a central portion 51a and a peripheral edge portion 51b. The central portion 51a can be moved vertically by the vertical drive unit 22.

The vertical drive unit 22 has a position detecting function, as in the first embodiment, and is connected to the temperature control unit 20. Therefore, as in the first embodiment, it enables the central portion 51a of the reflector 51 to move to a predetermined position within a stroke corresponding to the temperature distribution in the surface of the wafer w. Note that, as in the second embodiment, the vertical drive unit 22 may be formed integrally with a lifting unit for loading/unloading a wafer.

According to the present embodiment, it is possible to minimize reflection from a central portion of a heater, thereby enabling a selective control of a temperature at a central portion of a wafer. Accordingly, as in the first embodiment, it is possible to minimize variation in temperatures in the surface of the wafer w. It is also possible to minimize variation in temperatures in the surface of the wafer w which is associated with deterioration of heaters. Accordingly, the frequency of replacement of heaters can be reduced and the productivity can be improved.

### Forth Embodiment

A configuration of an epitaxial film formation apparatus according to the present embodiment is equal to that according to the first embodiment. However, a material with a high degree of reflectivity is arranged at a central portion of a reflector.

FIG. 8 shows a reflector of an epitaxial film formation apparatus, which is a semiconductor manufacturing device according to the present embodiment. Note that, in FIG. 8, the same reference numerals are used to designate constituent elements which are the same as those illustrated in FIG. 1, and the explanation is omitted.

As illustrated in FIG. 8, a disc-shaped reflector 61 is divided into a central portion 61a having TaC with a high degree of reflectivity (emissivity: ε=0.2) and a base material 61b having carbon (emissivity: s=0.7).

The vertical drive unit 22 has a position detecting function, as in the first embodiment, and is connected to the temperature control unit 20. Therefore, as in the first embodiment, it enables the reflector 61 to move to a predetermined position within a stroke corresponding to the temperature distribution in the surface of the wafer w.

Note that, as in the second embodiment, the vertical drive unit 22 may be formed integrally with a lifting unit for loading/unloading a wafer.

According to the present embodiment, it is possible to selectively control a temperature at a central portion of a wafer because reflection of the amount of heat from a central portion of a heater can be increased. Accordingly, as in the first embodiment, it is possible to minimize variation in temperatures in the surface of the wafer w. It is also possible to minimize variation in temperatures in the surface of the wafer w which is associated with deterioration of heaters. Accordingly, the frequency of replacement of heaters can be reduced and the productivity can be improved.

Note that, in the present embodiment, TaC is used as a material with a high degree of reflectivity, however, other materials such as glassy carbon (emissivity: ε=0.4) may be used.

According to the embodiments described above, it is possible to form a film such as an epitaxial film on a semiconductor wafer w with high productivity in a stable manner. It is also possible to improve the yields of wafers as well as the yields of semiconductor devices formed through an element formation process and an element separation process, and stability of element characteristics. In particular, excellent element characteristics can be obtained by application of the embodiments to an epitaxial formation process for a power semiconductor device such as a power MOSFET and an IGBT, which requires film thickness growth of equal to or larger than 100 μm in a N-type base region, P-type base region, an insulation separation region or the like.

In the present embodiment, there has been described a case in which a Si epitaxial film is formed. However, the present embodiment is also applicable to a case for the formation of an epitaxial layer of other compound semiconductors such as SiC, GaN, GaAlAs and In GaAs, a polysilicon layer, or an insulation layer such as SiO2 layer and Si3N4 layer. The present embodiment can be practiced in various forms without departing from the spirit and scope of the invention.

What is claimed is:

1. A vapor growth apparatus comprising:
a reaction chamber configured to load a wafer;
a gas supply mechanism configured to supply process gas into the reaction chamber;
a support unit configured to place the wafer;
a heater configured to heat the wafer from below;
a rotation control unit configured to rotate the wafer;
a gas exhaust mechanism including an exhaust port exhausting gas from the reaction chamber;
a reflector provided below the heater configured to reflect heat from the heater onto a rear face of the wafer; and
a vertical drive unit configured to vertically moving the reflector.

2. The vapor growth apparatus according to claim 1, wherein there is further provided, in the reaction chamber, a temperature detection unit configured to measure temperature distribution of a front face of the wafer that is placed on the support unit, and a measuring signal of the temperature detection unit is supplied to a temperature control unit, the temperature control unit controlling an exothermic temperature of the heater.

3. The vapor growth apparatus according to claim 2, wherein the t temperature detection unit includes a first thermometer detecting temperature distribution of a central portion and a second thermometer detecting temperature distribution of a peripheral edge portion.

4. The vapor growth apparatus according to claim 2, wherein the temperature control unit drives the vertical drive unit, thereby vertically moving the reflector so that the temperature distribution of the front face of the wafer is in a predetermined range of temperatures.

5. The vapor growth apparatus according to claim 1, wherein the vertical drive unit further moves the wafer upwardly.

6. The vapor growth apparatus according to claim 2, wherein a plurality of wafer lift pins are provided on a top face of the reflector in a standing manner, and the vertical drive unit vertically drives the reflector while, with the wafer lift pins, supporting the wafer that is loaded into the reaction chamber, thereby placing the wafer on the support unit.

7. The vapor growth apparatus according to claim 1, wherein a reflectivity of a central portion of the reflector is higher than that of a peripheral portion thereof.

8. The vapor growth apparatus according to claim 7, wherein the central portion consists of TaC or glassy carbon.

9. The vapor growth apparatus according to claim 8, wherein the peripheral portion consists of carbon.

10. The vapor growth apparatus according to claim 1, wherein the reflector is divided into a central portion and a peripheral portion, and the vertical drive unit vertically moves the central portion.

11. A vapor growth method comprising:
holding a wafer at a predetermined position inside a reaction chamber;
heating a rear face of the wafer with a heater while vertically moving a reflector that is provided below the heater, thereby heating the wafer at a predetermined temperature while controlling temperature distribution of the wafer; and
supplying process gas onto the wafer while rotating the wafer, thereby forming a film on the wafer.

12. The vapor growth method according to claim 11, comprising:
measuring temperature distribution of a front face of the wafer; and
performing the heating based on information of the temperature distribution.

13. The vapor growth method according to claim 12, wherein the temperature distribution is a temperature distribution of a central portion of the wafer and a peripheral edge portion of the wafer.

14. The vapor growth method according to claim 13, comprising vertically moving the reflector so that the temperature distribution of the front face of the wafer is in a predetermined range of temperatures.

15. The vapor growth method according to claim 11, comprising moving the wafer upwardly and downwardly with the reflector.

16. The vapor growth method according to claim 11, wherein a reflectivity of a central portion of the reflector is higher than that of a peripheral portion thereof.

17. The vapor growth method according to claim 11, wherein the central portion consists of TaC or glassy carbon.

18. The vapor growth method according to claim 17, wherein the peripheral portion consists of carbon.

19. The vapor growth method according to claim 11, comprising:
dividing the reflector into a central portion and a peripheral portion; and
separating the central portion from the peripheral portion, thereby vertically moving the central portion.
